(19) United States
(12) Patent Application Publication
(10) Pub. No.: US 2008/0224695 A1
(43) Pub. Date: Sep. 18, 2008

(54) Method of Measuring a Weak Magnetic Field and Magnetic Field Sensor of Improved Sensitivity

(75) Inventors: Paul Leroy, Bourg La Reine (FR); Frederic Nguyen Van Dau, Palaiseau (FR); Alain Friederich, Paris (FR)

Correspondence Address: LOWE HAUPTMAN & BERNER, LLP, 1700 DIAGONAL ROAD, SUITE 300, ALEXANDRIA, VA, 22314, US

(73) Assignee: THALES, Neuilly-Sur-Seine (FR)

(21) Appl. No.: 11/722,692

(22) PCT Filed: Dec. 19, 2005
(86) PCT No.: PCT/EP05/56890

§ 371 Date: Jun. 22, 2007

(30) Foreign Application Priority Data
Dec. 23, 2004 (FR) 0413831

(51) Int. Cl. G01R 33/09

(52) U.S. Cl. 324/252

(57) ABSTRACT

A magnetic field sensor comprises a magnetoresistive element (10) biased with a current (i) in order to measure an external magnetic field (Hₑₓₜ). A magnetic modulation field (Hₘ) is applied to a sensitive region of said sensor and the sensor comprises a synchronous detection device (14) for measuring the amplitude of an odd harmonic of the output signal.

### CROSS-REFERENCE TO RELATED APPLICATIONS

The present Application is based on International Application No. PCT/EP2005/056890 filed on Dec. 19, 2005 which in turn corresponds to France Application No 0413831 filed on Dec. 23, 2004 and priority is hereby claimed under 35 USC §119 based on these applications. Each of these applications are hereby incorporated by reference in their entirety into the present application.

### FIELD OF THE INVENTION

The present invention relates to weak-field magnetic field sensors and more particularly to magnetoresistive sensors used for measuring weak fields, that is to say fields not exceeding the Earth's magnetic field.

It should be noted that the notion of a weak field may be connected with the distance between the magnetic source and the sensor, or with the size of the magnetic source itself.

### BACKGROUND OF THE INVENTION

It will be recalled that a magnetoresistive sensor uses the magnetoresistance of ferromagnetic materials and nanostructures, that is to say the variation in the electrical resistance of a conductor under the effect of the magnetic field applied to it. In practice, such a sensor requires the application of a bias current i. The output voltage Vs obtained depends on the bias current i and on the magnetoresistance, and therefore makes it possible to determine the value of the applied magnetic field. Depending on the sensor, this voltage measurement is longitudinal, that is to say along the same direction as the current i, or transverse, that is to say in an orthogonal direction. It is known to produce such sensors for measuring weak fields, typically in a range from the order of 10⁻⁴ oersteds to a few oersteds (1 oersted=10⁴ tesla). They are typically produced by multilayer stacks with particular magnetic configurations. The sensitive region of the sensor may be very small. Such sensors may be produced on semiconductor substrates, thereby allowing monolithic integration of the sensor with associated signal processing electronics.

In particular, sensors employing giant magnetoresistance GMR or tunnel magnetoresistance TMR (or SDT, standing for Spin-Dependent Tunneling) are widely used in all fields of industry for detection or measurement. Magnetometers, altitude sensors, heading detection, mine detection, current sensors and magnetic signature sensors are examples of their use.

The invention relates more particularly to measurement, and therefore to sensors delivering, as output, a linear and reversible response, as a function of the applied field, over a certain measurement range.

### STATE OF THE ART

A GMR sensor comprises at least two separate ferromagnetic layers, the magnetization vectors of which may have different orientations in the plane depending on the external magnetic field. In particular, multilayer structures are known that comprise a repetition of an alternation of ferromagnetic conducting layers and nonferromagnetic conducting layers, which provide a large giant magnetoresistance effect. This giant magnetoresistance GMR effect is a reflection of the spin dependence of the resistance of this artificial magnetic structure. The overall exploitable effect is of the order of around 10% of the resistance of the sensitive region (in which the magnetic fields are produced) of the magnetic structure. An illustrative example of such a sensor is shown in FIG. 1. It corresponds to a structure described in French patent No. 98 15697. It comprises a stack in the form of a strip of two layers 1 and 2 of magnetic material that are separated by a nonmagnetic conducting material 3. For example, the stack 1/3/2 may be of the Co/Cu/FeNi type. The bias current i flows through all the conducting layers 1, 2 and 3. In the example, the voltage Vs is measured longitudinally.

An example of a TMR sensor, described in French patent No. 00 06453, is illustrated in FIG. 2. It comprises an FM1/I/FM2/AF multilayer stack, where FM1 and FM2 are two ferromagnetic metal layers (for example made of Co, Fe or NiFe), I is a thin insulating layer and AF is a layer of antiferromagnetic material (for example an antiferromagnetic material such as FeMn or IrMn). Such a structure exhibits tunnel magnetoresistance TMR (or SDT), reflecting the dependence of the current in the tunnel junction formed by the insulating barrier I, as a function of the relative orientations of the magnetizations on either side of this junction. This phenomenon corresponds to the conservation of the spin of the electrons when they pass through the insulating barrier by the tunnel effect. The current i flows between the conducting layers FM 1 and FM 2 through the insulating barrier I. The voltage Vs is measured across the terminals of the layers FM1 and FM2.

It is known to produce such GMR or TMR sensors with a magnetic configuration designed to deliver, as output, a linear and reversible response signal Vs as a function of the applied magnetic field, at least within a certain measurement range. The two aforementioned patents provide at least one example thereof.

One problem common with such magnetoresistive sensors is that, in weak-field measurement applications for which the sensor operates at low frequency, typically below 1 kilohertz, the precision of the output signal delivered by these sensors is mainly limited by the thermal drift of the signal. The thermal drift of the output signal is in fact the main noise component at low frequency (around 1 Hz) of these sensors. This is particularly troublesome, especially for measuring weak or zero fields.

As mentioned above, a magnetoresistive sensor receives a bias current i, and, in response, delivers at its terminals a voltage signal Vs representative of the external field Hₑₓₜ applied to the sensitive region of the sensor. Such a device is shown schematically in FIG. 3a.

The output signal Vs is illustrated in FIG. 3b and represents the variation in voltage as a function of the applied field Hₑₓₜ.

In general, the resistivity R of a GMR or TMR magnetoresistive sensor as a function of the applied magnetic field Hₑₓₜ is given by: R=R₀+S.Hₑₓₜ.

Assuming that the magnetic detection layer is a magnetic monodomain, then:

$$R = \frac{{V}_{s}}{i} = {R}_{0} + S \cdot {H}_{ext} ,$$

where Vs is the measured output voltage of the sensor, i is the bias current of the sensor, R₀ is the isotropic component (or offset) of the resistance, which varies with temperature, and S is the component that varies with the field Hₑₓₜ (that is to say the slope of the response curve).

The output voltage given by Vs=R.i may be expressed similarly: Vs=V₀+vs.

The corresponding normalized response curve as a function of the applied field Hₑₓₜ is that illustrated in FIG. 3b. Plotted on the y-axis is the variation vs of the output voltage Vs divided by the maximum voltage variation vsc that can be measured, obtained for Hₑₓₜ=H_{c}. Plotted on the x-axis is the normalized external field, i.e. Hₑₓₜ/H_{c}.

This response curve exhibits two saturation plateaus, one for a characteristic field H_{c}, corresponding to the value vs_{c}, and one for a characteristic field value −H_{c}. The characteristic field H_{c} depends on the specific properties of the structure of the sensor in question. It will be understood that the value of H_{c} may vary in magnitude, allowing a field of greater or lesser amplitude to be measured.

The field measurement signal comes from the second term of the equation (i.e. S.Hₑₓₜ) and leads in practice to a variation of a few fractions of a percent per oersted.

At the same time, R₀, the isotropic part of the resistance, varies with temperature by a few fractions of a percent per degree. This means, in other words, that if it is desired to produce a sensor precise to 1 millioersted, the ambient temperature in the sensor environment must be stable to better than 1 millikelvin. This is a problem that seems particularly difficult to solve.

Those skilled in the art have therefore sought to reduce the effects of this thermal drift. Solutions for reducing the effects of the offset resistance of GMR or TMR sensors are known, among which mention may be made of a method described in French patent No. 98 15697, which consists in taking two measurements between which the direction of magnetization is reversed and then in calculating the difference between the two results obtained. However, this method is limited by the coupling between the magnetic layers through the nonmagnetic spacer layer.

It is also known to use arrangements of the Wheatstone bridge type to solve the thermal drift problem of these magnetoresistive sensors. Such a solution may be found, for example, in the aforementioned French patents. Typically, it requires at least four sensors, one per arm. However, this solution poses a number of practical problems, especially that of producing the current leads. To be effective, it requires the offset resistances R₀ of the sensors to be identical, in order to balance the arms of the bridge. However, it is difficult to obtain identical offset resistances to better than 1% in the case of GMR sensors, which amounts to dividing the resistance R₀ by 100 in Equation 1. This problem is more complex in the case of TMR sensors, since the offset resistance R₀ of the tunnel junction of TMR sensors is an exponential function of the thickness d of the insulating barrier (R₀∝e^{+αd}). A fluctuation in the thickness d between two sensors of the bridge, even of very small amplitude, results in a significant imbalance of the bridge. The tolerance on the thickness d of the barrier, due to the technological fabrication constraints, makes it difficult in practice to balance a Wheatstone bridge. One solution described in the article entitled “Picotesla field sensor design using spin-dependent tunneling Devices” by Mark Tondra et al. in J. Appl. Phys. 83 (11), 6688 (1 Jun. 1998) consists in using, in each of the arms of the bridge, N tunnel junctions (i.e. N TMR sensors) arranged in series or in parallel. Thus, a statistical reduction in the noise by a factor \sqrt{N} is obtained. In order for such a solution to be effective, it is however necessary for N to be large enough, which makes the technological complexity of the device very great, in particular as regards producing the current leads. Moreover, the number N of elements needed is also a limiting factor.

Thus, in applications using weak-field sensors, the problem of thermal drift noise, which limits their sensitivity, has not been satisfactorily solved.

### BRIEF SUMMARY OF THE INVENTION

The object of the invention is to improve the sensitivity of magnetoresistive sensors, more particularly GMR or TMR sensors.

According to the invention, a magnetic field detection system comprises a magnetoresistive element through which a bias current flows and a device for applying a modulation field in a sensitive region of the magnetoresistive element, in such a way that one of the saturation plateaus (Hₑₓₜ=H_{c} or −H_{c}) of the variation of magnetoresistance is reached. The output voltage measured across the terminals of the magnetoresistive element depends on the external field to be measured and on the modulated field—it is the image of the variations in magnetoresistance with the total applied magnetic field.

It has been shown that this modulation makes it possible, as output, to factor out the offset R₀ of the magnetoresistance, so as to improve the sensitivity of the sensor.

The amplitude of the odd harmonics of the output signal thus obtained is linear around the zero field within a certain measurement range. The extraction of an odd harmonic of the output signal, at the modulation frequency, therefore gives a measurement of the external field, which is independent of the offset resistance R₀ of the sensor, and therefore of its thermal drift.

In practice, this field modulation is applicable for measuring a field Hₑₓₜ that is small compared with the amplitude Hₐ of the modulated field. Hₐ is determined in an appropriate manner, especially as a function of the saturation field H_{c} of the sensor in question.

Remarkably, the extraction of the third harmonic gives a direct measurement of the external field. However, the associated measurement range, corresponding to the linear region of the amplitude of this harmonic as a function of the field, is reduced.

In an improvement, the modulated field includes a DC component H₀, which may be varied in steps so as to extend the measurement region of the sensor, in ranges.

The value of this component H₀ may also be slaved by a feedback loop in order to impose a zero field on the sensitive region of the sensor. The value of the external field is then deduced from the value of the DC component H₀.

The invention therefore relates to a method of measuring a weak magnetic field employing a current-biased magnetoresistive element, including the application of a modulation field in a sensitive region of the magnetoresistive element and the extraction of an odd harmonic of an output signal from said magnetoresistive element, in order to deliver a measurement of said weak magnetic field on the basis of the amplitude of said harmonic.

The invention also relates to a magnetic field sensor for measuring a weak external magnetic field, comprising a magnetoresistive element and means for biasing said element with a current, and further including means for applying a frequency-controlled and amplitude-controlled magnetic modulation field, and a device for synchronously detecting an output signal from said element in order to measure the amplitude of an odd harmonic of the output signal.

Still other objects and advantages of the present invention will become readily apparent to those skilled in the art from the following detailed description, wherein the preferred embodiments of the invention are shown and described, simply by way of illustration of the best mode contemplated of carrying out the invention. As will be realized, the invention is capable of other and different embodiments, and its several details are capable of modifications in various obvious aspects, all without departing from the invention.

Accordingly, the drawings and description thereof are to be regarded as illustrative in nature, and not as restrictive.

### BRIEF DESCRIPTION OF THE DRAWINGS

FIG. 1 illustrates schematically a GMR sensor of the prior art;

FIG. 2 illustrates schematically a TMR sensor of the prior art;

FIGS. 3a and 3b show, respectively, a device for measuring an external magnetic field applied in a sensitive region of a magnetoresistive element and the associated response curve as a function of the amplitude of the applied external field;

FIG. 4 illustrates schematically a magnetic field measurement device according to the invention;

FIG. 5 shows another embodiment of a magnetic field measurement device according to the invention, comprising external means for generating a modulation field in a sensitive region of a magnetoresistive element;

FIG. 6 illustrates schematically a first embodiment of a measurement device according to the invention, comprising a conducting layer capable of generating a modulation field in the sensitive region of the magnetoresistive element according to the invention;

FIG. 7 gives the curves of the variation in output voltage of a magnetoresistive element as a function of an applied external field and as a function of the amplitude of the applied modulation field according to the invention;

FIG. 8 shows the amplitudes of the first four harmonics of the signal as a function of an external field, for a field of given amplitude modulation;

FIG. 9 shows in detail the amplitudes of the 1st and 3rd harmonics and the associated linear measurement region;

FIG. 10 illustrates the variation in amplitude of the 1st harmonic in the case in which the DC component of the modulation field is taken to be substantially equal to the characteristic saturation field H_{c} of the magnetoresistive element;

FIG. 11 is a block diagram of a circuit for selecting the measurement range, which may be used in the sensor according to the invention; and

FIG. 12 is a block diagram of a sensor according to the invention, with a feedback loop for slaving the DC component of the modulation field to the measured amplitude as output.

### DETAILED DESCRIPTION OF THE INVENTION

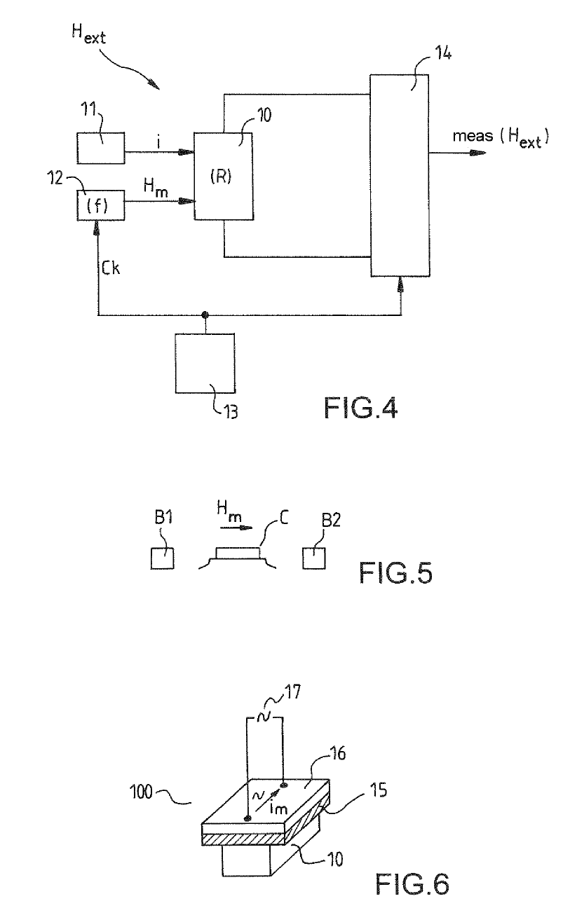

A sensor for measuring an external magnetic field Hₑₓₜ according to the invention comprises, as illustrated schematically in FIG. 4:
a magnetoresistive element 10 having a magnetoresistance R;
a generator 11 for generating a bias current i;
means 12 for generating a modulation field Hₘ at a modulation frequency f derived from a clock signal Clk, delivered for example by a local oscillator 13; and
a signal processing device 14 comprising a device for synchronous detection at the modulation frequency f of the output signal Vs of the magnetoresistive element 10. This electronic device delivers the result of the measurement mes(Hₑₓₜ) of the external field Hₑₓₜ.

In practice, the synchronous detection device is configured to detect the amplitude of an odd harmonic of the output signal. This harmonic is preferably the fundamental h1, detected at the modulation frequency f of the field Hₘ. In a variant, it is the third harmonic h3 that is detected at the frequency 3f.

In practice, the measurement device includes a frequency generator, typically a local oscillator, which delivers a reference clock signal Clk to the means 12 for generating the modulation field and to the electronic processing device 14.

The modulation means 12 may be external, nonintegrated means. Such a configuration is shown schematically in FIG. 5. The sensor then comprises a monolithic package C, in which the elements 10, 11 and 14 of FIG. 4 are integrated, and for example a pair of electromagnetic coils B1, B2 placed on either side of the package and appropriately controlled, typically by a sinusoidal current generator for generating the modulation field Hₘ in the environment of the package C.

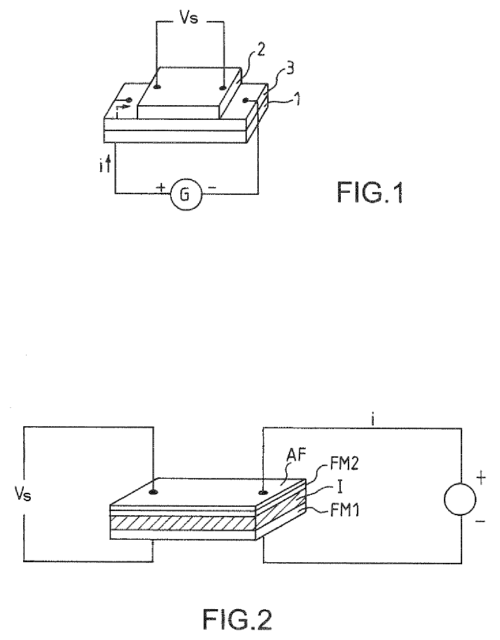

These means 12 may also be integrated into the structure of the magnetoresistive element 10, for example a structure as shown in FIG. 1 or FIG. 2. The sensor may then be integrated into a monolithic package. According to one embodiment illustrated in FIG. 6, the modulation means 12 comprise a conducting strip 16 appropriately placed on top of or underneath the magnetoresistive element 10. A modulation current iₘ, generated by a sinusoidal current generator 17 at the desired frequency f, is applied to this strip so as to create the modulation field Hₘ in the environment of the magnetoresistive element. A layer 15 of an insulator is provided between the surface of the magnetoresistive element and the conducting strip 16.

The strip 16 is preferably wider than the magnetoresistive element 10 so as to have a modulation field Hₘ that is homogeneous over the entire magnetoresistive element.

In practice, a person skilled in the art will adapt the integration of the conducting strip 16 according to the configuration of the magnetoresistive element in question.

The principle of measuring a field with a sensor according to the invention will now be explained, considering the case in which the sensitive magnetic detection region is a magnetic monodomain, resulting in a simplified mathematical expression. However, the invention is not limited to this particular case; rather it applies in general to any magnetic detection layer.

As is standard, the term “sensitive region” denotes the region where magnetoresistance effects occur, the practical definition of which depends on the structure of the magnetoresistive element.

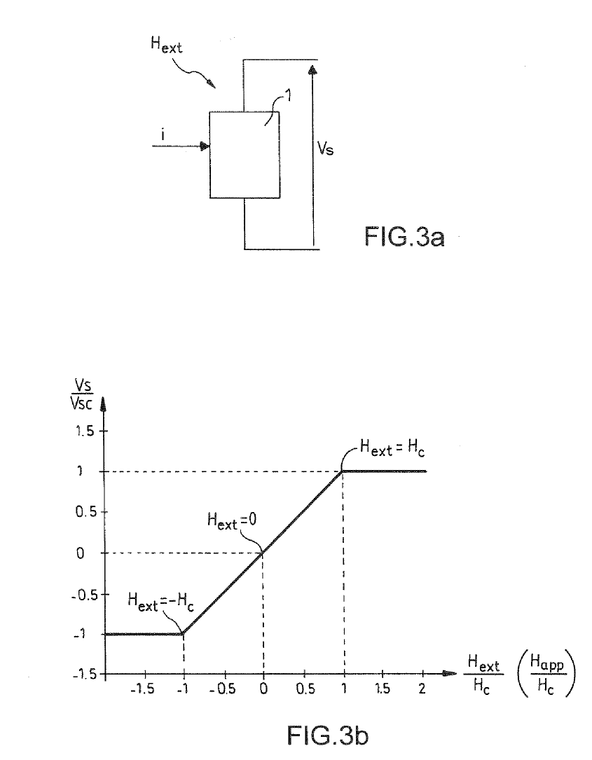

As seen above in relation to FIG. 3b, the magnetoresistance R of the magnetoresistive element 10 as a function of the applied external field Hₑₓₜ to the sensitive region of the sensor may be expressed as:

$$R = \frac{{V}_{s}}{i} = {R}_{0} + S \cdot {H}_{ext} = {R}_{0} + dR . \qquad ( Eq . 1 )$$

The output voltage given by Vs=Ri may be expressed similarly: Vs=V₀+vs.

The corresponding normalized response curve is that illustrated in FIG. 3b. It gives the variation vs of the output voltage Vs divided by the maximum voltage variation vs_{c} obtained for Hₑₓₜ equal to the saturation field H_{c} as a function of the applied field Hₑₓₜ. Plotted on the x-axis are the normalized external field values, i.e. Hₑₓₜ/H_{c}.

For Hₑₓₜ=0, dR (or vs)=0.

This response curve is composed of three straight segments, namely one of slope g1 around the zero field (Hₑₓₜ=0), and two of slope g2. The changes in slope occur for the characteristic field values −H_{c} and +H_{c} of the applied field—these are the field values for which the magnetoresistive element in question saturates.

According to the invention, the modulated field Hₘ is applied, this field generally comprising a DC component H₀ and a modulated component Hₐ, for example a sinusoidally modulated component.

This field Hₘ may be written as follows: Hₘ=H₀+Hₐcosθ, where Hₐ is the maximum amplitude of the variable component of the field Hₘ, and H₀ is its DC component. Hₐ is always positive. However, the amplitude of the AC component of the modulation field, Hₐcosθ, is alternately positive and negative. θ is equal to 2πift, where t is the time and f the frequency.

Denoting the external field to be detected by Hₑₓₜ, the total field applied to the magnetoresistive element is therefore given by:

Hₐₚₚ=Hₑₓₜ+H₀+Hₐcosθ (Eq. 2).

Equation 1 becomes:

$$R = \frac{{V}_{s}}{i} = {R}_{0} + S \cdot {H}_{app} = {R}_{0} + dR . \qquad ( Eq . 1 )$$

The output voltage Vs across the terminals of the sensor is modulated.

This modulation is chosen in such a way as to reach one of the saturation plateaus of the variation dR of the resistance R_{M}.

For example, it may be chosen to be on the positive saturation plateau, obtained for an applied total field amplitude of +H_{c}.

Having chosen the modulation field, and since the values of H₀ and Hₐ are fixed with H₀>0, the study is limited to measuring an external field, the values of which lie within the following interval:

Hₐ<H_{c} and H_{c}−H₀−Hₐ<Hₑₓₜ<H_{c}−H₀+Hₐ. (Cond. 1)

Under these conditions, H₀ has a positive or zero value. Preferably, H₀ is taken to be equal to the characteristic saturation field, i.e. H₀=H_{c}.

Preferably, Hₐ is chosen to be close or equal to the saturation field H_{c} so as to benefit from the largest measurement range.

Equally well it is possible to choose to be on the other saturation plateau. The modulation conditions are deduced from Equation 2 and from condition 1 (Cond. 1) given above. A person skilled in the art will, where appropriate, adapt the various equations so as to be on the other saturation plateau. In particular, H₀ will be negative or zero, preferably equal to the characteristic saturation field, i.e. H₀=−H_{c}.

In the following, the positive saturation plateau will be considered. According to the invention, the modulation field is such that the total field Hₐₚₚ has excursions on either side of H_{c}, which means that there is a field modulation around the saturation plateau.

Considering FIG. 3b again, between the two saturation plateaus, i.e. for a total field Hₐₚₚ of less than H_{c} (in absolute value), the output voltage is given by:

Vs=g1.Hₐₚₚ=g1 (Hₑₓₜ+H₀+Hₐcosθ).

After the positive saturation plateau, i.e. for Hₐₚₚ greater than H_{c}, the output voltage Vs of the device is written as:

Vs=g1.H_{c}+g2(Hₐₚₚ−H_{c}), which is also equal to

Vs=g1.H_{c}+g2(Hₐcosθ−Hₐcosθ₀)

where θ₀ is the angle defined by:

Hₑₓₜ+H₀+Hₐcosθ₀=H_{c}, i.e. cosθ₀=(Hₑₓₜ+H₀₋−H_{c})/Hₐ.

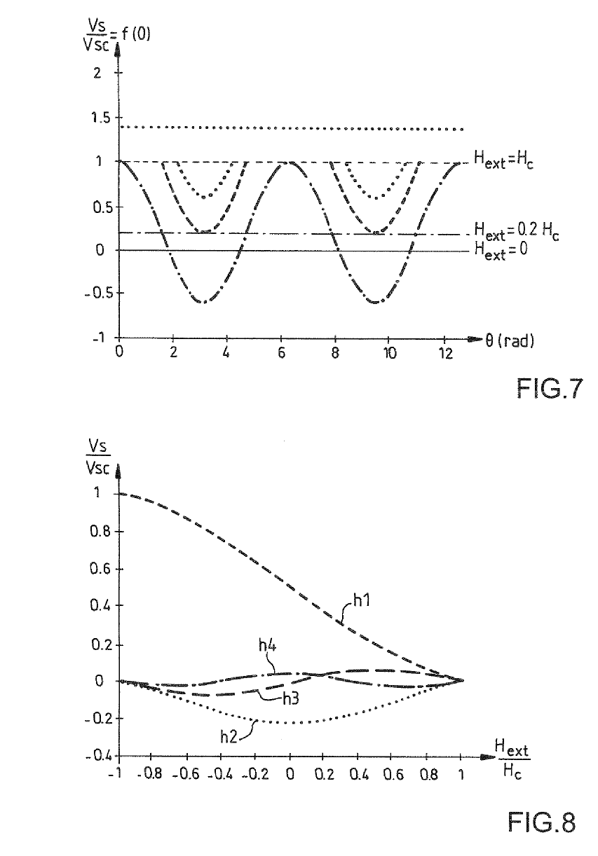

FIG. 7 shows the f(θ) curves of the variation of the normalized output voltage Vs/Vsc as a function of θ, with the following modulation parameters: Hₐ=0.8H_{c} and H₀=0.

Each curve corresponds to a different value of the external field Hₑₓₜ to be measured.

It may be seen that the function f(θ) is an even function, namely f(θ)=f(−θ).

Expansion as a Fourier series is therefore a sum of a cosine term and a DC component.

FIG. 8 shows the amplitude of the first four harmonics of the output signal Vs as a function of the external field to be measured (again in normalized representation). These curves were obtained in practice by numerical simulation, taking as parameters the field modulation Hₘ, Hₐ=H_{c}, and H₀=H_{c}: thus we have the fundamental mode h1 (with a nonzero offset h₁⁰ of 0.5), the second harmonic h2, the second harmonic h 3 and the fourth harmonic h4.

It may be noted that the even harmonics, i.e. h2 and h4, are even functions of the field so that they cannot be used for measuring the external field.

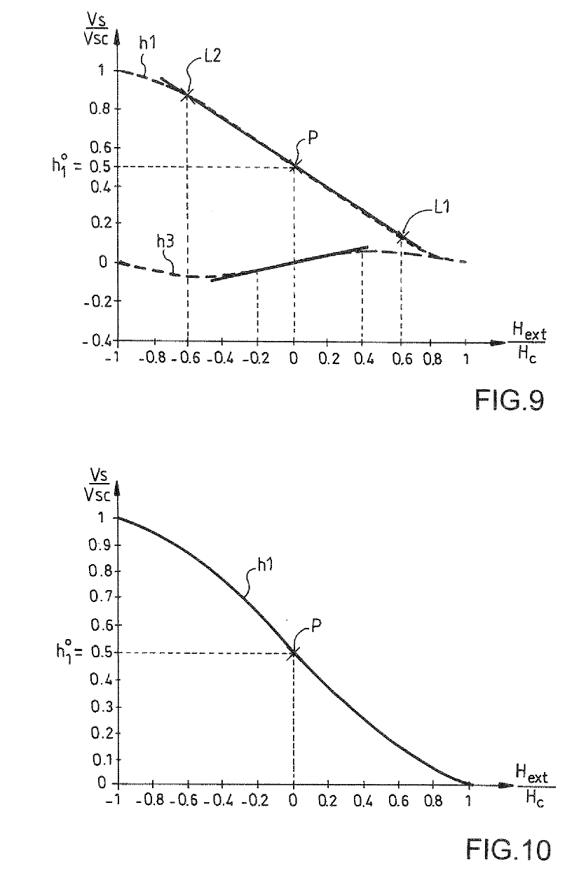

However, the odd harmonics h1 and h3 exhibit a linear variation about the zero field. FIG. 9 (the same field modulation conditions as in FIG. 8) shows these linear portions of the variation of the amplitude of the harmonics h1 and h3 with the external field Hₑₓₜ to be measured. To simplify the description, the same notation hⱼ is used to denote a harmonic and its amplitude.

Considering the fundamental mode, it may be shown that its amplitude h1 is given by:

$$h 1 = {H}_{a} \frac{g 2 - g 1}{π} ar cos ( \frac{{H}_{c} - {H}_{ext} - {H}_{0}}{{H}_{a}} ) + \frac{g 1 - g 2}{π} \cdot \frac{{H}_{c} - {H}_{ext} - {H}_{0}}{{H}_{a}} \sqrt{{H}_{a}^{2} - {( {H}_{c} - {H}_{ext} - {H}_{0} )}^{2}} + g 1 \cdot {H}_{a} . \qquad ( Eq . 3 )$$

This amplitude h1 of the fundamental is therefore independent of the offset value of the transfer function of the sensor, and therefore independent of the thermal drift.

Its derivative may be expressed as:

$$\frac{d h 1}{d {H}_{ext}} = 2 \frac{g 2 - g 1}{π} \sqrt{1 - {( \frac{{H}_{c} - {H}_{ext} - {H}_{0}}{Ha} )}^{2}}$$

It may be shown that its derivative is a maximum for H_{c}=Hₑₓₜ+H₀.

This property is interesting as it indicates that there is a maximum measurement sensitivity at the point P (FIGS. 8 and 9) where H₀=H_{c}, with a maximum measurement scale around this point.

It is therefore beneficial to choose the DC component H₀ of the modulation field Hₘ to be nonzero, and preferably substantially equal to H_{c}.

This is because, with H₀=H_{c}, the amplitude of the first harmonic hi given by the formula (Eq.3) becomes:

$$h 1 = {H}_{a} \frac{g 2 - g 1}{π} ar cos ( \frac{- {H}_{ext}}{{H}_{a}} ) + \frac{g 1 - g 2}{π} \cdot \frac{- {H}_{ext}}{{H}_{a}} \sqrt{{H}_{a}^{2} - {H}_{ext}^{2}} + g 1 \cdot {H}_{a} . \qquad ( Eq . 4 )$$

The plot of this amplitude h1 as a function of the external field Hₑₓₜ to be measured (in normalized values) is given in FIG. 10 (corresponding to the simulation conditions of FIG. 8). This shows that there is a linear portion in the measurement range from −0.4 H_{c} to +0.4 H_{c}.

These properties of the fundamental mode show that it is easy to obtain a measurement of the external field Hₑₓₜ knowing the parameters g1 and g2 of the transfer function of the sensor and the amplitude Hₐ of the modulation field Hₘ.

Indeed, within the context of interest here, namely how to measure weak or zero fields, the amplitude Hₐ of the modulating field is large compared with the field Hₑₓₜ to be measured. Under these conditions, the expansion limited to the first order in Hₑₓₜ/Hₐ of this equation (Eq. 4) gives the following equation:

$$h 1 = {H}_{a} \frac{g 2 - g 1}{π} ( \frac{π}{2} + \frac{{H}_{ext}}{{H}_{a}} ) + \frac{g 1 - g2}{π} {H}_{ext} + g 1 \cdot {H}_{a}$$

which gives:

$$h 1 = \frac{g 1 + g 2}{2} {H}_{a} + 2 \frac{g 2 - g 1}{π} {H}_{ext} . \qquad ( Eq . 5 ) .$$

The demodulated output signal, i.e. the h1 measurement, includes an offset (the first term of Eq. 5) and a useful term (the second term of Eq. 5) directly proportional to the quantity sought, i.e. Hₑₓₜ.

Hₑₓₜ is therefore expressed as a function of the amplitude of the harmonic h1, measured as output Vs of the magnetoresistive element 10, characteristics g1 and g2 of the transfer function of the magnetoresistive element 10, and the amplitude Hₐ of the applied modulation. The measurement of Hₑₓₜ therefore comprises subtracting the offset, which depends only on the characteristics g1, g2 of the transfer function of the magnetoresistive element 10 and the amplitude Hₐ of the applied modulation. This is carried out in practice by an electronic processing unit suitable for deducing the measurement of the external field as a function of g1, g2 and Hₐ.

The output voltage of a magnetoresistive sensor is small. In the invention, this is made to correspond to an output signal Vs at a nonzero modulation frequency f. Another advantage of the invention is therefore the frequency transposition of the output signal, if the sensor is followed by an amplifying electronic unit. This frequency transposition makes the amplification easier and contributes to improving the signal/noise ratio of the measurement, since the working frequency f is then far from the region (at around 1 hertz) where the low-frequency noise of the amplifying electronic unit occurs. In one example, the modulation frequency f is of the order of 10 kHz.

In one embodiment of the invention, a directly exploitable measurement signal corresponding to the external field Hₑₓₜ is obtained.

In this embodiment, the third harmonic h3 of the output signal of the magnetoresistive element is extracted.

It is worth pointing out that, for the amplitude h3 of the third harmonic shown in FIG. 8, the corresponding offset h₃⁰ obtained at zero field is practically zero. This harmonic therefore provides a direct measurement of the external field Hₑₓₜ. However, the measurement range is then narrower, the linear section being shorter than in the case of the first harmonic h1 and the sensitivity given by the slope of the linear section is lower than for the first harmonic h1. Typically, for h3 this range is from −0.35 H_{c} to +0.35 H_{c}.

An improvement of the invention therefore consists in using the DC component H₀ of the modulation field to make a field translation, depending on the value of the field Hₑₓₜ to be measured. The extent of measurement is enlarged by introducing the notion of measurement ranges.

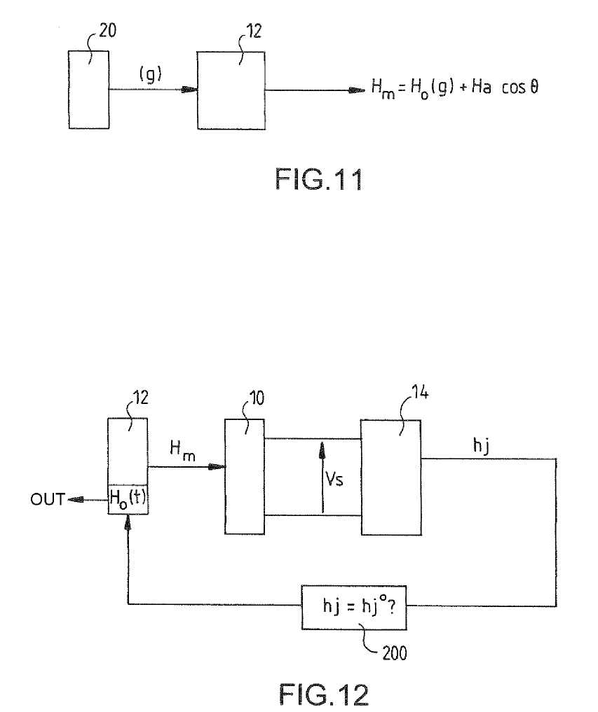

Thus, depending on the external field to be measured, and as illustrated schematically in FIG. 11, the device according to the invention comprises a circuit 20 for selecting a range g from among n measurement ranges. Depending on the range g selected, a value H₀(g) is obtained. A diagram of the corresponding device is shown in FIG. 11.

Typically, H₀(g) is equal to H_{c} plus or minus a multiple of a quantity ΔH₀. By default, H₀ is equal to H_{c}. In practice, the range may be selected manually or automatically. This selection is useful for extending the dynamic measurement range of a sensor using the third harmonic h3 for the measurement. However, it also applies to the fundamental h1.

Referring to FIG. 9, the change of range is made each time the amplitude of the harmonic h1 lying at the limit of the measurement range, near the point L1 or the point L2, is reached. The change of range is obtained by modifying the value of H₀ so as to again be in a measurement region close to the point P.

In another embodiment shown in FIG. 12, which may be applied equally well for a measurement based on either h1 or h3, this DC component H₀ is controlled by a feedback loop 200 so that a zero field on the magnetoresistive element is measured as output. The value of the external field Hₑₓₜ is then deduced from the value of H₀.

Considering for example the case of the harmonic h1, the normalized curve of variation with Hₑₓₜ of which is given in FIG. 9, the feedback control operation is performed by the feedback loop 200 so as to be always at the point P of coordinates h1=0.5 (=offset, denoted by h₁⁰) and Hₑₓₜ=0.

The feedback control operation then consists in varying the DC component H₀ of the modulation field Hₘ so as always to have h1=0.5.

A similar feedback control operation may be carried out in the case of the harmonic h3. In this case, it is carried out so as always to have h3=0.

The slaved value H₀(t) (stabilized value) therefore gives the value of the external field: H₀(t)=H_{c}+Hₑₓₜ. Thus, the external field is given by: Hₑₓₜ=H_{c}−H₀(t).

A practical embodiment of such a device with a feedback loop 200 is shown schematically in FIG. 12. The value of the DC component H₀ of the modulation field Hₘ is slaved to the output measurement value of the harmonic hⱼ so as to be equal to the offset value hⱼ⁰. The output value OUT of the device for measuring the external field Hₑₓₜ is then calculated as indicated above, from the value of H₀(t) after stabilization of the loop.

The invention that has just been described is applicable in all cases where weak fields are involved. It is not limited to the use of GMR and TMR magnetoresistances but applies to any magnetic configuration with a magnetoresistance having a response that is linear and reversible as a function of the applied field as a function of the applied field, and similar to that illustrated in FIG. 3b. Thus, the invention may also be applied to AMR (anisotropic magnetoresistance) elements.

The modulation, demodulation and DC-component feedback control means are produced by any suitable electronic device known to those skilled in the art.

It will be readily seen by one of ordinary skill in the art that the present invention fulfills all of the objects set forth above. After reading the foregoing specification, one of ordinary skill in the art will be able to affect various changes, substitutions of equivalents and various aspects of the invention as broadly disclosed herein. It is therefore intended that the protection granted hereon be limited only by the definition contained in the appended claims and equivalent thereof.

1. A method of measuring a weak magnetic field by a current-biased magnetoresistive element, comprising the following steps:
applying a modulation field in a sensitive region of the magnetoresistive element and extracting an odd harmonic of an output signal from the magnetoresistive element, in order to deliver a measurement of said magnetic field on the basis of the amplitude of said extracted harmonic.

2. The measurement method as claimed in claim 1, comprising extracting the fundamental mode.

3. The measurement method as claimed in claim 1, comprising extracting the third harmonic.

4. The measurement method as claimed in claim 1, wherein the applied magnetic modulation field has a variable component, the maximum amplitude of which is equal to or below a characteristic saturation field of said magnetoresistive element.

5. The measurement method as claimed in claim 1, wherein the applied magnetic modulation field has a DC component.

6. The measurement method as claimed in claim 5, wherein said DC component is equal to a characteristic saturation field of said magnetoresistive element.

7. The measurement method as claimed in claim 5, including a feedback loop that slaves the value of said DC component to the amplitude of said measured harmonic as output.

8. The measurement method as claimed in claim 5, including a selector for selecting a measurement range, said selector determining a value of the DC component of the modulation field as a function of the amplitude of said measured harmonic as output.

9. A magnetic field sensor for measuring a weak external magnetic field, comprising a magnetoresistive element and means for biasing said element with a current, further including means for applying a frequency-controlled and amplitude-controlled magnetic modulation field in an active region of said element, and a device for synchronously detecting an output signal from said element in order to measure the amplitude of an odd harmonic of the output signal.

10. The magnetic field sensor as claimed in claim 9, including a device for synchronously detecting the fundamental of the output signal.

11. The magnetic field sensor as claimed in claim 9, including a device for synchronously detecting the third harmonic of the output signal.

12. The magnetic field sensor as claimed in claim 9, wherein the applied magnetic modulation field has a variable component, the maximum amplitude of which is equal to or below the characteristic saturation field of said magnetoresistive element.

13. The magnetic field sensor as claimed in claim 9, wherein the applied magnetic modulation field has a DC component.

14. The magnetic field sensor as claimed in claim 13, wherein said DC component is equal to a characteristic saturation field of said magnetoresistive element.

15. The magnetic field sensor as claimed in claim 13, including a feedback loop that slaves the value of said DC component to the amplitude of said measured harmonic as output.

16. The magnetic field sensor as claimed in claim 13, including a selector for selecting a measurement range, said selector determining the value of the DC component.

17. The magnetic field sensor as claimed in claim 9, wherein the means for applying the magnetic modulation field are integrated into the structure of said magnetoresistive element, said means comprising a conducting strip placed on top of or underneath a sensitive region of said magnetoresistive element.

18. The magnetic field sensor as claimed in claim 9, wherein the means for applying the magnetic modulation field are external to the magnetoresistive element.

19. The magnetic field sensor as claimed in claim 9, wherein said means comprise a pair of coils as source of a magnetic field.

20. The magnetic field sensor as claimed in claim 4, wherein said magnetoresistive element is an element exhibiting giant magnetoresistance or an element exhibiting tunnel magnetoresistance.
